(19) United States
(12) Patent Application Publication
(10) Pub. No.: US 2001/0036733 A1
(43) Pub. Date: Nov. 1, 2001

(54) Method of fabricating thin-film transistor

(76) Inventors: Fang-Chan Luo, Hsinchu (TW); Chien-Sheng Yang, Taipei (TW)

Correspondence Address: J.C. Patents, Inc., 1340 Reynolds Ave., Suite 114, Irvine, CA, 92614, US

(21) Appl. No.: 09/843,985

(22) Filed: Apr. 27, 2001

(30) Foreign Application Priority Data
Apr. 28, 2000 (TW) 89108112

(51) Int. Cl. H01L 21/302; H01L 21/4763; H01L 21/461

(52) U.S. Cl. 438/689

(57) ABSTRACT

A method of fabricating a thin-film transistor on an insulation substrate. A gate and a gate line are formed on the insulation substrate. A gate dielectric layer, a silicon layer, a doped silicon layer and a conductive layer are formed over the insulation substrate. The conductive layer and the doped silicon layer are patterned to form a source/drain line, while the conductive layer and the doped silicon layer on the gate remain. A transparent conductive layer is formed over the insulation substrate. The transparent conductive layer, the conductive layer and the doped silicon layer are patterned to respectively form a pixel electrode, a source/drain conductive layer and a source/drain region. A protection layer is then formed over the insulation layer. The protection layer is patterned to expose the pixel electrode. The method of fabricating the thin-film transistor can be applied to fabrication of fax machine, CIS such as scanner and various electronic devices. It can also be applied to fabrication of normal thin-film transistor flat panel display such as liquid crystal display (LCD) and organic light emitting diode (OLED).

### CROSS-REFERENCE TO RELATED APPLICATION

This application claims the priority benefit of Taiwan application serial no. 89108112, filed Apr. 28, 2000.

### BACKGROUND OF THE INVENTION

1. Field of the Invention

The invention relates in general to a method of fabricating a thin-film transistor (TFT). More particularly, this invention relates to a method of fabricating a thin-film transistor using four photomasks. In addition to the applications of fax machine, contact image sensor (CIS) such as a scanner and various electronic devices, this method can also applied to fabrication of thin-film transistor flat panel display such as liquid crystal display (LCD) and organic light-emitting diode (OLED).

2. Description of the Related Art

A thin-film transistor flat panel display basically comprises a thin-film transistor device and a liquid crystal display device. The thin-film transistor device further comprises more than one thin-film transistor arranged as an array. Each thin-film transistor corresponds to one pixel electrode. The thin-film transistors are formed by formations of a gate, a gate dielectric layer, a channel layer and a source/drain region stacked on an insulation substrate. The thin-film transistors in the thin-film transistor liquid crystal display are normally used as switching devices.

In FIG. 1A, an insulation substrate 100 is provided. A conductive layer is sputtered on the insulation substrate 100. The conductive layer of a single or multiple layers (such as a composite layer) is made of at least one type or multiple types of metal, or alloy thereof. Using a first photolithography and etching process, the conductive layer is patterned as a gate 110 and a gate line.

In FIG. 1B, a silicon nitride layer (SiNₓ) 120, a hydrogenated amorphous silicon layer (a-Si:H) 130 and a doped amorphous silicon layer (n⁺ a-Si) 140 are formed in sequence on the insulation substrate 100. A second photolithography and etching step is performed to pattern the doped amorphous silicon layer 140 and the hydrogenated amorphous silicon layer 130. As shown in FIG. 1B, the patterned doped amorphous silicon layer 140 and the doped hydrogenated amorphous silicon layer 130 are aligned over the gate 110.

In FIG. 1C, a conductive layer is sputtered on the insulation substrate 100. The conductive layer of a single or multiple layers (such as a composite layer) is made of at least one type or multiple types of metal or alloy thereof. Further using a third photolithography and etching process, the metal layer 150 and the underlying doped amorphous silicon layer 140 are patterned to form a source/drain line 150a, a source/drain metal layer 150 and a source/drain region 140a.

In FIG. 1D, a silicon nitride protection layer 160 is formed over the insulation substrate 100. A fourth photolithography and etching step is performed to form an opening 166 in the silicon nitride protection layer 160. The opening 166 exposes a portion of the source/drain metal layer 150.

In FIG. 1E, an indium tin oxide layer (ITO) 170 is sputtered over the substrate 100. A fifth photolithography and etching step is performed to form a pixel electrode 170.

As mentioned above, the conventional method requires five photolithography and etching steps to form the thin-film transistor. For each photolithography and etching step, processes such as dehydration bake, priming, photoresist coating, soft bake, exposure, post-bake of exposure, development, hard bake, etching and photoresist stripping are performed. Thus, each additional photolithography and etching step greatly increases the fabrication cost. Furthermore, the yield of products decreases as they undergo each additional photolithography and etching step.

### SUMMARY OF THE INVENTION

The invention provides a method of fabricating a thin-film transistor. The method can be applied to fabrication of fax machine, contact image sensor (CIS) such as scanner and various electronic devices. In addition, the method can also be applied to fabrication of thin-film transistor flat panel display such as liquid crystal display and organic light-emitting diode (OLED).

An insulation substrate is provided. A gate/gate line is formed on the insulation substrate. A gate dielectric layer, a silicon layer, a doped silicon layer and a conductive layer are formed on the insulation substrate sequentially. The conductive layer , the doped silicon layer and the silicon layer are then patterned to form a source/drain line and to have portions of the conductive layer and the doped silicon layer remained over the gate/gate line. A transparent conductive layer is formed over the insulation substrate. The transparent conductive layer, the patterned conductive layer and the patterned doped silicon layer are patterned to form a pixel electrode, a source/drain conductive layer and a source/drain region. A protection layer is formed over the insulation layer and then is patterned to expose the pixel electrode.

Accordingly, the transparent conductive layer used to form the pixel electrode is formed prior to the formation of the protection layer. Therefore, the formation of the pixel electrode, the source/drain region conductive layer and the source/drain region requires only one photolithography and etching step. Thus, the number of photolithography and etching steps is reduced from 5 to 4. The fabrication process is simplified, and the fabrication cost is decreased. Furthermore, the yield of the product is enhanced.

Both the foregoing general description and the following detailed description are exemplary and explanatory only and are not restrictive of the invention, as claimed.

### BRIEF DESCRIPTION OF THE DRAWINGS

FIGS. 1A to 1E show a conventional method for fabricating a thin-film transistor of a thin-film transistor liquid crystal display; and

FIGS. 2, 3A, 4A, 5A and 6A are cross sectional views showing a fabrication process for a thin-film transistor of a thin-film transistor liquid crystal display according to the invention; and

FIGS. 3B, 4B, 5B and 6B are top views of the fabrication process of the thin-film transistor as shown in FIG. 3A to FIG. 6A.

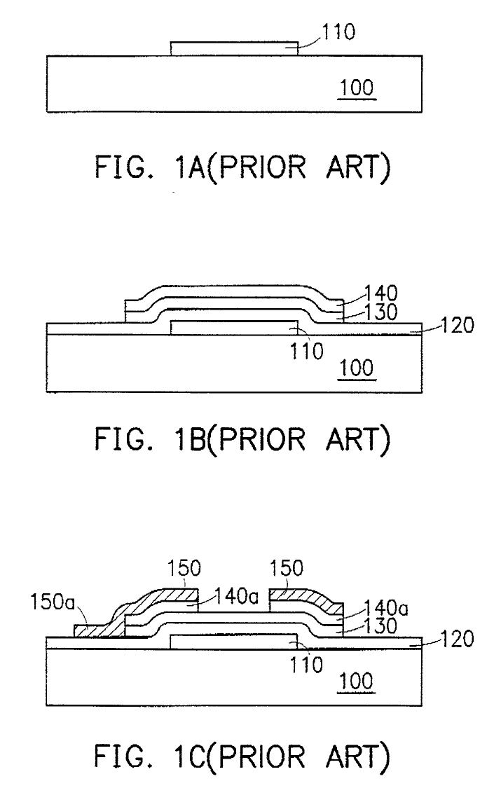

### DESCRIPTION OF THE PREFERRED EMBODIMENTS

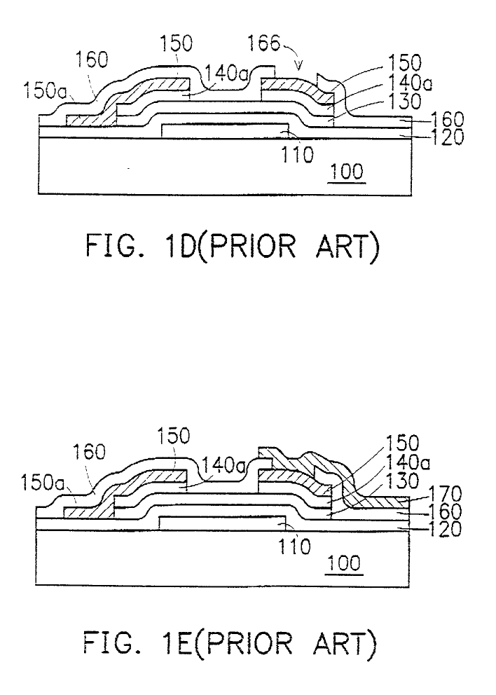

In FIG. 2, an insulation substrate 200 is provided. A conductive layer 210 of a single or composite layer made of one or more than one metal or alloy is formed on the insulation substrate. The metal or alloy is selected from at least one of aluminium, copper, gold, silver, molybdenum, chromium, titanium and tungsten. In one preferred embodiment, the conductive layer includes at least a titanium/aluminium/titanium composite layer. The titanium/aluminium/titanium composite layer also includes the alloy thereof. When the aluminium alloy is selected, neodymium may be included.

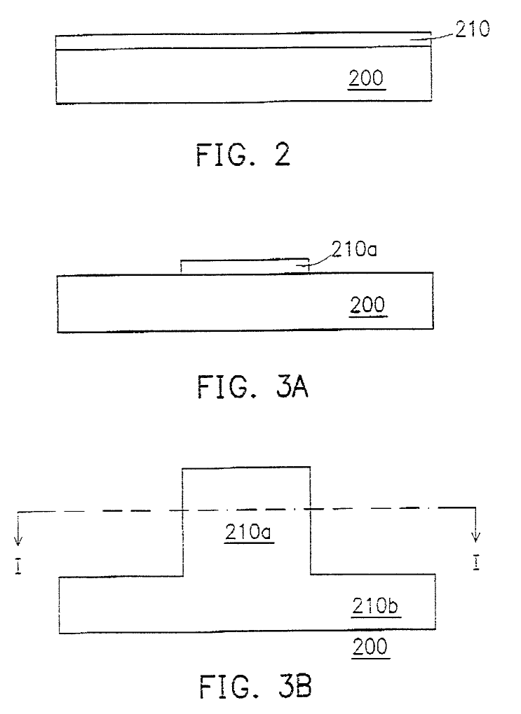

In FIG. 3A, a first step of photolithography and etching is performed to pattern the conductive layer 210 so that a gate 210a and a gate line 210b are formed. FIG. 3B is a top view of the gate 210 and the gate line 210b, while FIG. 3A is the cross sectional view along the cutting line I-I in FIG. 3B.

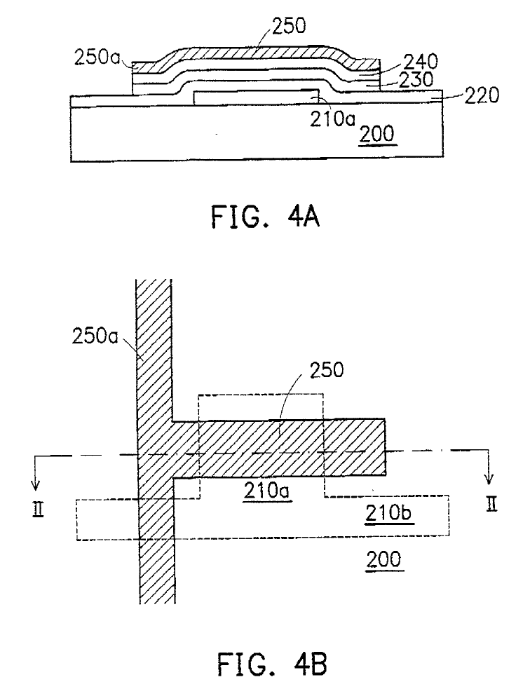

FIG. 4A is a cross sectional view cutting along II-II in FIG. 4B. In FIG. 4A, a gate dielectric layer 220, a silicon layer 230, a doped silicon layer 240 and a conductive layer 250 are formed in sequence on the insulation substrate 200. The material of the gate dielectric layer 220, the silicon layer 230 and the doped silicon layer 240 comprise, for example, silicon nitride, amorphous silicon and N-type amorphous silicon, respectively. The conductive layer 250 includes a single or composite layer made of one or more than one kind of metal or alloy. The metal or alloy is selected from aluminium, copper, gold, silver, molybdenum, chromium, titanium and tungsten. When an aluminium alloy is selected, neodymium may be included. In one preferred embodiment, the conductive layer includes at least a titanium/aluminium/titanium composite layer. The titanium/aluminium/titanium composite layer also includes the alloy thereof. When the aluminium alloy is selected, neodymiummay be included.

A second step of photolithography and etching is performed on the conductive layer 250, the doped silicon layer 240 and silicon layer 230. As shown in FIG. 4B, a source/drain line 250a is formed over the insulation substrate 200 across the gate line 210b, while a portion of the conductive layer 250, a portion of the doped silicon layer 240 and a portion of silicon layer 230 are aligned over the gate 210a.

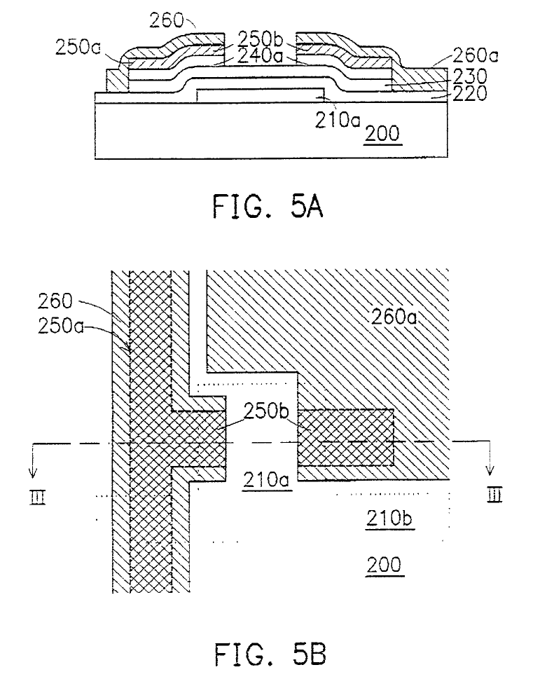

In FIG. 5A and FIG. 5B, a transparent conductive layer 260, for example, comprising an indium tin oxide layer, is formed over the insulation substrate 200. A third step of photolithography and etching step is performed. The transparent conductive layer 260, a portion of conductive layer 250 and a portion of the doped silicon layer 240 are patterned. As a result, the silicon layer 230 aligned over the gate 210b and a portion of the gate line 210a are exposed. Being patterned, the portion of conductive layer 250 is bisected into two parts of source/drain conductive lines 250b. A first part of the source/drain conductive lines 250b extends from the source/drain line 250a over one side of the gate 210a, while a second part is located over the other side of the gate 210b. The patterned doped silicon layer 240a also comprises a source/drain region 240a underlying the source/drain line 250a and the source/drain conductive line 250b. The transparent conductive layer 260 is patterned into a remaining portion covering the source/drain line 250a and the first part of the source/drain conductive layer 250b, and a pixel electrode 260a covering the second part of the source/drain conductive line 250b.

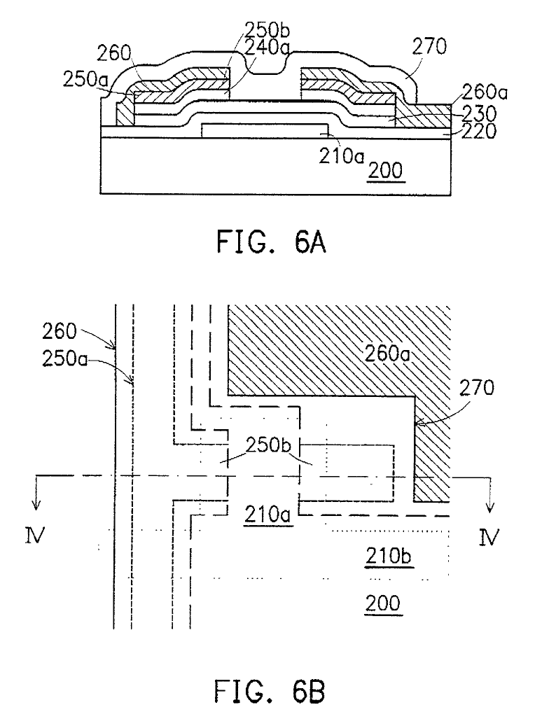

In FIG. 6A and FIG. 6B, a protection layer 270, for example, comprising a silicon nitride layer, is formed and patterned over the insulation substrate 200. The protection layer 270 is patterned by a fourth photolithography and etching step to expose a portion of the pixel electrode 260a out of a position over the gate 210a and the gate line 210b.

Using the above method to fabricate a TFTLCD, only four photolithography and etching steps are performed. Formation of the pixel electrode 260a, the source/drain conductive layer 250b and the source/drain region 240a requires only one photolithography and etching step. That is, one photomask is used for patterning the transparent conductive layer 260, the conductive layer 250 and the doped silicon layer 240. The fabrication process is thus simplified to result in a lower fabrication cost. Moreover, the yield of product is enhanced as a result of undergoing fewer processes.

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

What is claimed is:

1. A method of fabricating a thin-film transistor, comprising:
providing an insulation substrate;
forming a first conductive layer on the insulation substrate;
patterning the first conductive layer to form a gate and a gate line on the conductive layer by performing a first step of photolithography and etching;
forming a gate dielectric layer, a silicon layer, a doped silicon layer and a second conductive layer over the insulation substrate in sequence;
performing a second step of photolithography and etching on the a silicon layer, a doped silicon layer and a second conductive layer, so that a source/drain line is formed, and remaining portions of the second conductive layer, the doped silicon layer and the silicon layer are aligned over the gate;
forming a transparent conductive layer on the insulation substrate;
performing a third step of photolithography and etching on the transparent conductive layer, the remaining portions of the second conductive layer, the remaining portions of the doped silicon layer and the remaining portions of the doped silicon layer to form a pixel electrode, a source/drain conductive layer and a source/drain region;
forming a protection layer over the substrate; and
performing a fourth step of photolithography and etching to expose a portion of the pixel electrode.

2. The method according to claim 1, wherein the step of forming the first conductive layer comprises a step of forming a single or a composite layer made of one or multiple layers of various metals and alloys.

3. The method according to claim 2, wherein the metals and alloys are selected from a group consisting of aluminum, copper, gold, silver, molybdenum, chromium, titanium and tungsten.

4. The method according to claim 3, wherein neodymium is also included when aluminum alloy is selected.

5. The method according to claim 1, wherein the step of forming the first conductive layer comprising a step of forming at least a titanium/aluminum/titanium composite layer, including titanium alloy and aluminum alloys.

6. The method according to claim 5, wherein the aluminum alloy comprises neodymium.

7. The method according to claim 1, wherein the step of forming the gate dielectric layer comprises a step of forming a silicon nitride layer.

8. The method according to claim 1, wherein the step of forming the silicon layer comprises a step of forming an amorphous silicon layer.

9. The method according to claim 1, wherein the step of forming the doped silicon layer comprises a step of forming an N-type amorphous silicon layer.

10. The method according to claim 1, wherein the step of forming the second conductive layer comprises a step of forming a single or a composite layer made of one or multiple layers of various metals and alloys.

11. The method according to claim 10, wherein the metals and alloys are selected from a group consisting of aluminum, copper, gold, silver, molybdenum, chromium, titanium and tungsten.

12. The method according to claim 11, wherein neodymium is also included when aluminum alloy is selected.

13. The method according to claim 1, wherein the step of forming the first conductive layer comprising a step of forming at least a titanium/aluminum/titanium composite layer, including titanium alloy and aluminum alloys.

14. The method according to claim 13, wherein the aluminum alloy comprises neodymium.

15. The method according to claim 1, wherein the step of forming the transparent conductive layer comprises a step of forming an indium tin oxide layer.

16. The method according to claim 1, wherein the step of forming the protection layer comprises a step of forming a silicon nitride layer.

17. The method according to claim 1 is used for forming a thin-film transistor flat panel display including a liquid crystal display and an organic light-emitting diode.

18. The method according to claim 1 is used for forming a fax machine and a CIS.

19. A method of fabricating a thin-film transistor, comprising:
performing a first deposition, photolithography and etching step to form a gate and a gate line on the insulation substrate;
performing a second deposition, photolithography and etching step to form a source/drain line over the insulation substrate;
performing a third deposition, photolithography and etching step to form a pixel electrode, a source/drain conductive layer and a source/drain region over the insulation substrate, wherein the pixel electrode is located on the source/drain conductive layer and the source/drain region; and
performing a fourth deposition, photolithography and etching step to form a patterned protection layer over the insulation layer, wherein the protection layer exposes a portion of the pixel electrode.

20. The method according to claim 19, further comprising the steps of:
forming a doped silicon layer and a conductive layer in sequence on the insulation substrate in the second step of deposition, photolithography and etching; and
patterning the conductive layer and the doped silicon layer to form the source/drain line.

21. The method according to claim 11, wherein the step of forming the pixel electrode, the source/drain conductive layer and the source/drain region further comprises the steps of:
aligning remaining portions of the patterned conductive layer and the pattern doped silicon layer over the gate;
forming a transparent conductive layer over the insulation substrate; and
patterning the transparent conductive layer, the conductive layer and the doped silicon layer to form the pixel electrode, the source/drain conductive layer and the source/drain region.

22. The method according to claim 19, wherein the step of forming the gate and the gate line comprises a step of forming a single layer or a composite layer selected from at least one metal or alloy.

23. The method according to claim 22, wherein the metal and alloy are selected from one or more of a group consisting of aluminum, copper, gold, silver, molybdenum, chromium, titanium and tungsten.

24. The method according to claim 23, wherein the aluminum alloy further comprises neodymium.

25. The method according to claim 19, wherein the step of forming the gate and gate line comprise a step of forming at least a titanium/aluminum/titanium composite layer, wherein the titanium and aluminum comprise titanium alloy and aluminum alloy.

26. The method according to claim 25, wherein the aluminum alloy comprises neodymium.

27. The method according to claim 19, wherein the step of forming the silicon layer comprises a step of forming an amorphous silicon layer.

28. The method according to claim 19, wherein the step of forming the silicon layer comprises a step of forming at least an amorphous silicon layer.

29. The method according to claim 19, wherein the step of forming the source/drain conductive layer and the source/drain line structure comprise a step of forming a single or a multiple layers made of one or more kinds of metals or alloys.

30. The method according to claim 19, wherein the metals and alloys are selected from a group consisting of aluminum, copper, silver, molybdenum, chromium, and tungsten.

31. The method according to claim 29, wherein the alloy of aluminum further comprises neodymium.

32. The method according to claim 19, wherein the step of forming the source/drain line and the source/drain conductive layer includes at least a titanium/aluminum/titanium layer, wherein the titanium layer and the aluminum layer include titanium alloy and aluminum alloy.

33. The method according to claim 32, wherein the aluminum alloy includes neodymium.

34. The method according to claim 19, wherein step of forming the source/drain region includes a step of forming an N-type doped amorphous silicon layer.

35. The method according to claim 19, wherein the step of forming the transparent protection layer comprises a step of forming of an indium tin oxide layer.

36. The method according to claim 19, wherein the step of forming the protection layer includes a step of forming a silicon nitride layer.

37. The method according to claim 19 is a step of a method for fabricating a liquid crystal display and organic light-emitting diode.

38. The method according to claim 19 is a step of a method for fabricating a fax machine and a contact image sensor.
